(19) United States
(12) Patent Application Publication
(10) Pub. No.: US 2025/0351409 A1
(43) Pub. Date: Nov. 13, 2025

(54) MANUFACTURING METHOD OF METAL OXIDE SEMICONDUCTOR TRANSISTOR

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Hitoshi FUJIOKA, Nisshin-shi (JP); Tsunenobu KIMOTO, Kyoto (JP)

(21) Appl. No.: 19/171,702

(22) Filed: Apr. 7, 2025

(30) Foreign Application Priority Data
May 13, 2024 (JP) 2024-078202

(51) Int. Cl. H10D 30/01; H01L 21/28

(52) U.S. Cl. CPC H10D 30/0297; H01L 21/28185; H01L 21/28194

(57) ABSTRACT

In a manufacturing method of a metal oxide semiconductor transistor, a surface of a silicon carbide (SiC) substrate is etched by heating the SiC substrate in hydrogen gas. After the surface of the SiC substrate is etched, a silicon film is formed on the surface of the SiC substrate by heating the SiC substrate in a gas containing hydrogen gas and a silicon source gas to a temperature lower than a heating temperature of the SiC substrate in the etching, and a gate insulating film made of silicon oxide is formed on a surface of the silicon film. After the gate insulating film is formed, a nitrogen termination process is carried out on the SiC substrate.

### CROSS REFERENCE TO RELATED APPLICATION

The present application claims the benefit of priority from Japanese Patent Application No. 2024-078202 filed on May 13, 2024. The entire disclosure of the above application is incorporated herein by reference.

### TECHNICAL FIELD

The present disclosure relates to a manufacturing method of a metal oxide semiconductor (MOS) transistor.

### BACKGROUND

A manufacturing method of a MOS transistor is known, in which a surface of a silicon carbide (SiC) substrate is etched by hydrogen gas, and a silicon (Si) film is formed on the surface of the SiC substrate by heating the SiC substrate in a gas containing hydrogen and a silicon source gas.

### SUMMARY

A manufacturing method of a MOS transistor according to one example of the present disclosure includes: etching a surface of an SiC substrate by heating the SiC substrate in hydrogen gas; after carrying out the etching, growing a silicon film on the surface of the SiC substrate by heating the SiC substrate in a gas containing hydrogen gas and a silicon source gas to a temperature lower than a heating temperature of the SiC substrate in the etching; forming a gate insulating film made of silicon oxide on a surface of the silicon film; and after the forming of the gate insulating film, carrying out a nitrogen termination process on the SiC substrate.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of a MOS transistor;

FIG. 2A is a diagram illustrating a process of preparing an SiC substrate in a manufacturing method of the MOS transistor according to one embodiment;

FIG. 2B is a diagram illustrating a process of forming a trench in the manufacturing method of the MOS transistor according to the one embodiment;

FIG. 2C is a diagram illustrating a process of forming a sacrificial oxide film in the manufacturing method of the MOS transistor according to the one embodiment;

FIG. 2D is a diagram illustrating a process of removing the sacrificial oxide film in the manufacturing method of the MOS transistor according to the one embodiment;

FIG. 3A is a diagram illustrating a high-temperature hydrogen etching process in the manufacturing method of the MOS transistor according to the one embodiment;

FIG. 3B is a diagram illustrating a silicon film forming process in the manufacturing method of the MOS transistor according to the one embodiment;

FIG. 3C is a diagram illustrating a gate insulating film forming process in the manufacturing method of the MOS transistor according to the one embodiment;

FIG. 3D is a diagram illustrating a gate electrode forming process in the manufacturing method of the MOS transistor according to the one embodiment;

FIG. 4A is a diagram illustrating occurrence of an aggregation portion of silicon;

FIG. 4B is a diagram illustrating a remaining aggregation portion of silicon after a trench gate structure is completed; and

FIG. 5 is a graph showing the relationship between the SiC substrate heating temperature and the number of detected aggregation portions.

### DETAILED DESCRIPTION

In a manufacturing method of a MOS transistor, an SiC substrate may be heated in a gas containing hydrogen gas and a silicon source gas. Then, a surface of the SiC substrate may be etched by the hydrogen gas, and a silicon (Si) film may be formed on the surface of the SiC substrate. Next, a silicon oxide film (that is, SiO₂) may be formed as a gate insulating film on a surface of the silicon film. At this time, the silicon film is oxidized, thereby suppressing oxidation of the surface of the SiC substrate. When the oxidation of the surface of the SiC substrate is suppressed in this manner, an interface state density at an interface between the silicon oxide film and the SiC substrate can be reduced. When the interface state density at the interface between the silicon oxide film and the SiC substrate is reduced, a channel mobility is improved and a channel resistance is reduced. Thus, it is possible to reduce an on-resistance of the MOS transistor. After the silicon oxide film is formed, a nitrogen termination process may be carried out. The nitrogen termination process can further reduce the interface state density at the interface between the silicon oxide film and the SiC substrate.

However, in the above-described manufacturing method, silicon may aggregate in a portion of the surface of the SiC substrate when the silicon film is grown. As a result, leakage current may occur through the silicon aggregation portion.

A manufacturing method of a MOS transistor according to one aspect of the present disclosure includes: etching a surface of an SiC substrate by heating the SiC substrate in hydrogen gas; after carrying out the etching, growing a silicon film on the surface of the SiC substrate by heating the SiC substrate in a gas containing hydrogen gas and a silicon source gas to a temperature lower than a heating temperature of the SiC substrate in the etching; forming a gate insulating film made of silicon oxide on a surface of the silicon film; and after the forming of the gate insulating film, carrying out a nitrogen termination process on the SiC substrate.

In the manufacturing method according to the one aspect, after the surface of the SiC substrate is etched, the silicon film is formed at the temperature lower than the heating temperature in the etching. The etching of the SiC substrate is carried out at a high temperature, so that the surface of the SiC substrate can be adequately cleaned. Since the forming of the silicon film is carried out at a lower temperature than the etching, silicon migration is less likely to occur on the surface of the SiC substrate during the forming of the silicon film. Therefore, the silicon film can be formed uniformly while suppressing aggregation of silicon. In the forming of the gate insulating film, the silicon film is oxidized to form silicon oxide. This suppresses oxidation of the surface of the SiC substrate, making it difficult for an interface state to occur at an interface between the gate insulating film and the SiC substrate. Thereafter, SiC crystal is terminated with nitrogen at the interface between the gate insulating film and the SiC substrate by the nitrogen termination process. As described above, according to this manufacturing method, it is possible to manufacture the MOS transistor having a low interface state density at the interface between the gate insulating film and the SiC substrate while suppressing aggregation of silicon.

The manufacturing method according to the one aspect may further include forming a trench on the surface of the SiC substrate, the etching of the surface of the SiC substrate may include etching a side surface of the trench, the growing of the silicon film may include growing the silicon film on the side surface of the trench, and the forming of the gate insulating film may include forming the gate insulating film on the surface of the silicon film covering the side surface of the trench. According to this manufacturing method, aggregation of silicon on the side surface of the trench can be suppressed.

In the manufacturing method according to the one aspect, the growing of the silicon film may include controlling the temperature of the SiC substrate to 1100° C. or less. According to this manufacturing method, aggregation of silicon can be suppressed more effectively.

In the manufacturing method according to the one aspect, the growing of the silicon film may include controlling the temperature of the SiC substrate to a temperature equal to or higher than a decomposition temperature of the silicon source gas. According to this manufacturing method, it is possible to grow the silicon film appropriately.

In the manufacturing method according to the one aspect, the growing of the silicon film may be carried out so that the silicon film has a thickness of 6 nm or less. According to this manufacturing method, it is possible to appropriately oxidize the silicon film in the forming of the gate insulating film.

In the manufacturing method according to the one aspect, the etching of the surface of the SiC substrate and the growing of the silicon film may be carried out in the same chamber. According to this manufacturing method, it is possible to manufacture the MOS transistor effectively.

The manufacturing method according to the one aspect may further include forming a sacrificial oxide film on the surface of the SiC substrate and then removing the sacrificial oxide film before the etching of the surface of the SiC substrate. According to this manufacturing method, it is possible to remove defects and the like on the surface of the SiC substrate.

In the manufacturing method according to the one aspect, the surface of the SiC substrate may be a surface of an epitaxial layer.

In the manufacturing method according to the one aspect, the forming of the gate insulating film may be carried out by chemical vapor deposition.

In the manufacturing method according to the one aspect, the nitrogen termination process may include heating the SiC substrate to a temperature of 1200° C. or higher in nitrogen gas or nitrogen oxide gas. According to this manufacturing method, it is possible to further reduce the interface state density.

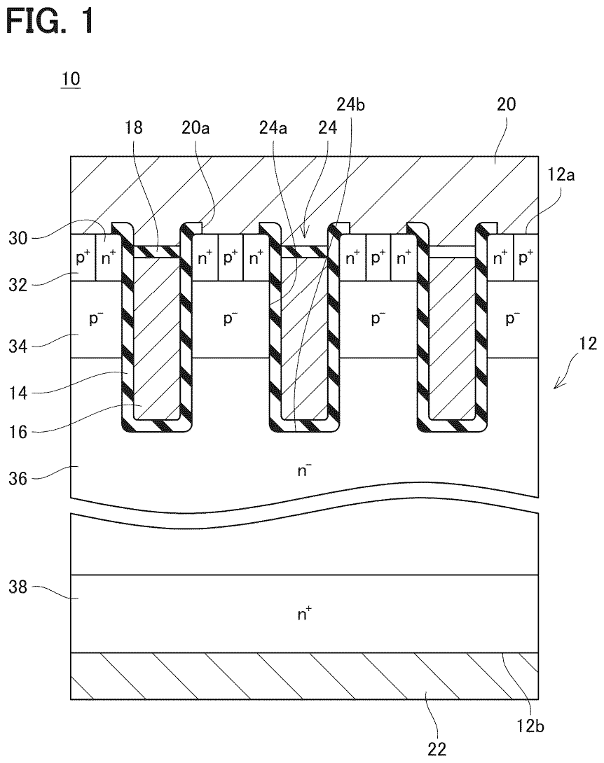

The following describes one embodiment of the present disclosure with reference to the drawings. FIG. 1 shows a MOS transistor 10 manufactured by a manufacturing method according to the one embodiment. The MOS transistor 10 includes an SiC substrate 12, a gate insulating film 14, a gate electrode 16, an interlayer insulating film 18, a source electrode 20, and a drain electrode 22. The SiC substrate 12 has an upper surface 12a and a lower surface 12b as main surfaces. A plurality of trenches 24 are provided on the upper surface 12a of the SiC substrate 12. The trenches 24 extend linearly and parallel to each other on the upper surface 12a. The gate insulating film 14 covers an inner surface of each of the trenches 24 (that is, a side surface 24a and a bottom surface 24b of each of the trenches 24). A gate electrode 16 is disposed inside each of the trenches 24. The gate electrode 16 is insulated from the SiC substrate 12 by the gate insulating film 14. The interlayer insulating film 18 covers an upper surface of the gate electrode 16. A source electrode 20 covers the upper surface 12a of the SiC substrate 12 and an upper surface of the interlayer insulating film 18. The source electrode 20 is insulated from the gate electrode 16 by the interlayer insulating film 18. A drain electrode 22 covers the lower surface 12b of the SiC substrate 12.

The SiC substrate 12 has a source region 30, a contact region 32, a body region 34, a drift region 36, and a drain region 38. The source region 30 is an n-type region having a high n-type impurity concentration. The source region 30 is in contact with the source electrode 20 and the gate insulating film 14. The contact region 32 is a p-type region having a high p-type impurity concentration. The contact region 32 is in contact with the source electrode 20. The body region 34 is a p-type region having a lower p-type impurity concentration than the contact region 32. The body region 34 is in contact with the source region 30 and the contact region 32 from below. The body region 34 is in contact with the gate insulating film 14 at a position below the source region 30. The drift region 36 is an n-type region having a lower n-type impurity concentration than the source region 30. The drift region 36 is in contact with the body region 34 from below. The drift region 36 is in contact with the gate insulating film 14 at a position below the body region 34. The drain region 38 is an n-type region having a higher n-type impurity concentration than the drift region 36. The drain region 38 is in contact with the drift region 36 from below. The drain region 38 is in contact with the drain electrode 22.

When a potential equal to or higher than a threshold value is applied to the gate electrode 16, a channel is formed in the body region 34 along the gate insulating film 14 (that is, the side surface 24a of each of the trenches 24). The channel connects the source region 30 and the drift region 36. When a potential higher than that of the source electrode 20 is applied to the drain electrode 22 in a state where the channel is formed, electrons flow from the source region 30 through the channel and the drift region 36 to the drain region 38.

Next, as the one embodiment, the manufacturing method of the MOS transistor 10 will be described. Since the manufacturing method of the present embodiment is characterized by a method of forming a gate structure, the method of forming the gate structure will be mainly described below.

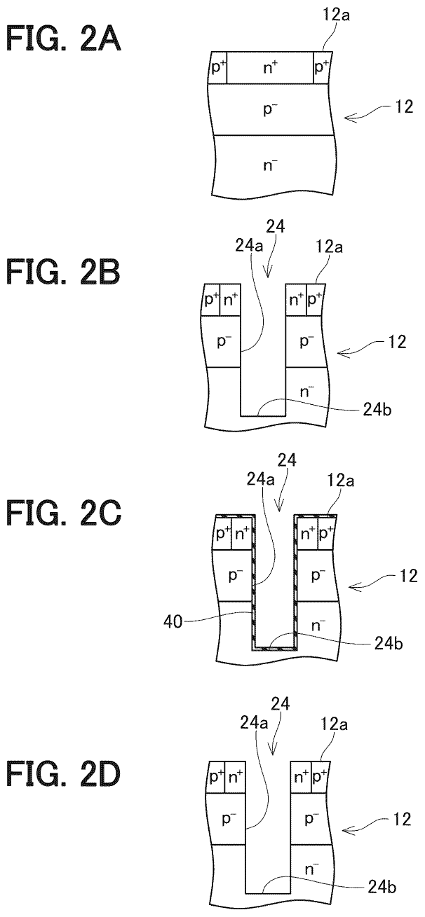

As shown in FIG. 2A, the SiC substrate 12 before forming trenches is prepared. An SiC layer exposed on the upper surface 12a is an epitaxial layer (that is, an SiC layer formed by epitaxial growth). An n⁺-region, a p⁺-region, a p⁻-region, and an n⁻-region shown in FIG. 2A are the source region 30, the contact region 32, the body region 34, and the drift region 36, respectively. Although not shown, the drain region 38 is disposed on the lower surface side of the SiC substrate 12 in FIG. 2A.

First, as shown in FIG. 2B, the upper surface 12a of the SiC substrate 12 is selectively etched to form the trench 24 on the upper surface 12a. The trench 24 penetrates the source region and the body region and reaches the drift region.

Next, as shown in FIG. 2C, the SiC substrate 12 is heated and oxidized to form a sacrificial oxide film 40 (that is, a silicon oxide film) on the upper surface 12a and the inner surface (that is, the side surface 24a and bottom surface 24b) of the trench 24. Next, as shown in FIG. 2D, the sacrificial oxide film 40 is removed by etching. In this manner, by forming the sacrificial oxide film 40 on the surface of the SiC substrate 12 and then removing the sacrificial oxide film 40, defects and contamination can be removed from the surface of the SiC substrate 12.

The process of forming the sacrificial oxide film and the process of removing the sacrificial oxide film are not essential and may be omitted. Regardless of whether the process of forming the sacrificial oxide film and the process of removing the sacrificial oxide film are carried out or not, carbon defects having C-C bonds are present at a high density on the surface of the SiC substrate 12. The carbon defects form an interface state and trap electrons. If carbon defects are present at a high density at an interface between the channel and the gate insulating film 14 (that is, on the side surface 24a of the trench 24), Coulomb scattering occurs due to electrons and the like captured at the interface state, and the channel resistance is increased. In contrast, as described below, in the manufacturing method of the present embodiment, the gate structure can be formed in a state in which an interface state density on the side surface 24a of the trench 24 is low.

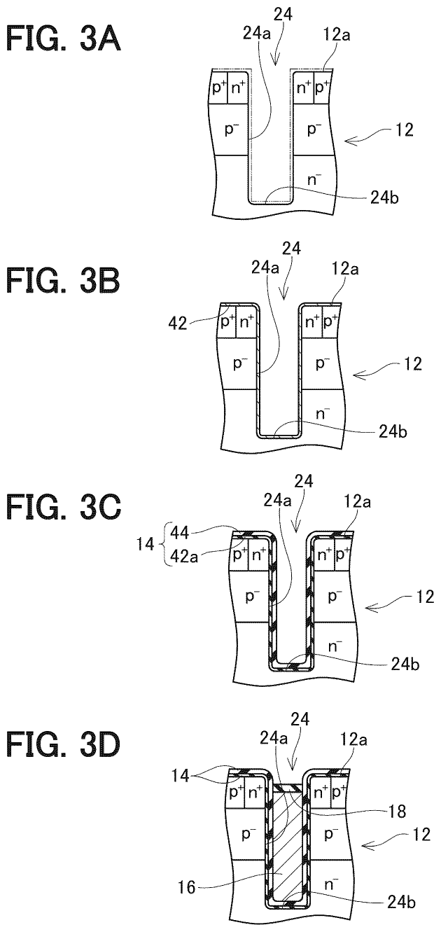

Next, a high-temperature hydrogen etching process shown in FIG. 3A is carried out. In the high-temperature hydrogen etching process, first, the SiC substrate 12 is placed in a chamber of a chemical vapor deposition (CVD) apparatus, and hydrogen (H₂) gas is supplied into the chamber. In the high-temperature hydrogen etching process, no silicon source gas is supplied into the chamber. Next, the SiC substrate 12 is heated in hydrogen gas to a temperature of 1200° C. or higher (for example, 1300° C.). Then, the surface of the SiC substrate 12 (that is, the upper surface 12a and the inner surface of the trench 24) is etched by the hydrogen gas. In the present embodiment, a very thin layer near the surface of the SiC substrate 12 is etched. As a result, carbon defects can be removed from the surface of the SiC substrate 12. That is, the high-temperature hydrogen etching process can reduce a carbon defect density on the surface of the SiC substrate 12.

Next, a silicon film forming process shown in FIG. 3B is carried out. The silicon film forming process is carried out consecutively in the same chamber as the high-temperature hydrogen etching process. By carrying out the high-temperature hydrogen etching process and the silicon film forming process in the same chamber, the quality of the manufactured MOS transistors can be stabilized and the manufacturing efficiency of the MOS transistors can be increased. In the silicon film forming process, hydrogen gas and silicon source gas are supplied into the chamber. The silicon source gas is a gas containing silicon atoms, and serves as a source of a silicon film 42 to be formed. As the silicon source gas, for example, silane (SiH₄) or the like can be used. Next, the SiC substrate 12 is heated in hydrogen gas and silicon source gas. In this process, a temperature of the SiC substrate 12 is controlled to be higher than a decomposition temperature of the silicon source gas and lower than the heating temperature in the high-temperature hydrogen etching process. For example, the temperature of the SiC substrate 12 can be controlled to a temperature higher than 400° C. (that is, the decomposition temperature of silane) and lower than or equal to 1100° C. In the silicon film forming process, a reaction in which the SiC substrate 12 is etched by hydrogen gas occurs on the surface of the SiC substrate 12 (that is, the upper surface 12a and the inner surface of the trench 24) and a reaction in which the silicon film 42 of single crystal is formed on the surface of the SiC substrate 12 by the silicon source gas occurs in parallel. In this way, the etching reaction and the film formation reaction occur in parallel, so that the silicon film 42 grows on the surface of the SiC substrate 12 in a clean state. Furthermore, since the etching reaction and the film forming reaction occur in parallel, the silicon film 42 having a thin thickness of 6 nm or less is formed in the silicon film forming process.

Next, a gate insulating film forming process shown in FIG. 3C is carried out. In this process, a low pressure CVD apparatus is used to form a silicon oxide layer 44 on the surface of the silicon film 42. That is, the silicon oxide layer 44 is formed on an upper portion of the upper surface 12a and in the trench 24. When the silicon oxide layer 44 is formed, the silicon film 42 is oxidized. A silicon oxide film 42a formed by oxidizing the silicon film 42 is integrated with the silicon oxide layer 44 formed by CVD. As a result, the gate insulating film 14 is formed.

Next, a nitrogen termination process is carried out. In the nitrogen termination process, the SiC substrate 12 is heated to a temperature of 1200° C. or higher (for example, 1250° C.) in nitrogen gas (that is, N₂ gas) or nitrogen oxide gas (that is, NO gas, N₂O gas, or the like). As a result, the SiC crystal is terminated with nitrogen.

Next, as shown in FIG. 3D, the gate electrode 16 is formed in the trench 24. In addition, the interlayer insulating film 18 is formed on the gate electrode 16. Thereby, the trench gate structure is completed. Next, as shown in FIG. 1, the gate insulating film 14 on the upper surface 12a is selectively removed to form contact holes 20a. Then, the source electrode 20 is formed so as to cover the upper surface 12a of the SiC substrate 12. Next, the drain electrode 22 is formed so as to cover the lower surface 12b of the SiC substrate 12. Through the above processes, the MOS transistor 10 shown in FIG. 1 is completed.

Next, a manufacturing method of Comparative Example 1 and the manufacturing method of the present embodiment will be described in comparison. In the manufacturing method of Comparative Example 1, the silicon oxide layer 44 is formed directly on the surface of the SiC substrate 12 without forming the silicon film 42. When the silicon oxide layer 44 is formed in this manner, the surface of the SiC substrate 12 is oxidized during the formation of the silicon oxide layer 44. In this case, the surface of the SiC substrate may be oxidized in the subsequent nitrogen termination process. For example, when nitrogen oxide gas is used in the nitrogen termination process, the surface of the SiC substrate may be oxidized by oxygen atoms in the nitrogen oxide gas. Even when nitrogen gas is used in the nitrogen termination process, the surface of the SiC substrate may be oxidized by a small amount of oxidizing gas mixed into the chamber. When the surface of the SiC substrate is oxidized in the gate insulating film forming process and the nitrogen termination process, carbon defects are generated on the surface of the SiC substrate.

In contrast, in the manufacturing method of the present embodiment, the silicon film 42 is oxidized instead of the SiC substrate 12 in the gate insulating film forming process and the nitrogen termination process. By oxidizing the silicon film 42 instead of the SiC substrate 12, oxidation of the surface of the SiC substrate 12 is suppressed. Therefore, carbon defects are unlikely to be generated on the surface of the SiC substrate 12 (that is, the interface between the SiC substrate 12 and the gate insulating film 14). This makes it possible to reduce the interface state density at the interface between the SiC substrate 12 and the gate insulating film 14. Due to this effect and the effect of terminating the SiC crystal with nitrogen by the nitrogen termination process, the interface state density at the interface between the SiC substrate 12 and the gate insulating film 14 can be significantly reduced. Therefore, it is possible to manufacture the MOS transistor 10 having a low interface state density on the side surface 24a (that is, the interface between the body region 34 and the gate insulating film 14). Therefore, according to this manufacturing method, the channel mobility of the MOS transistor 10 can be increased. Therefore, according to this manufacturing method, the MOS transistor 10 having a low on-resistance can be manufactured.

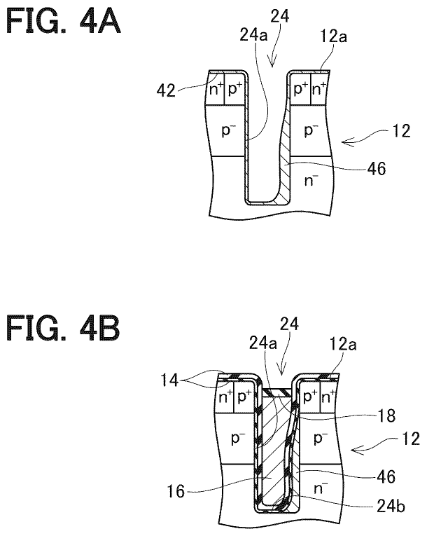

Next, a manufacturing method of Comparative Example 2 and the manufacturing method of the present embodiment will be described in comparison. In the manufacturing method of Comparative Example 2, the high-temperature hydrogen etching process is not carried out, and the silicon film forming process is carried out. In the silicon film forming process of Comparative Example 2, the SiC substrate 12 is heated in hydrogen gas to a temperature of 1200° C. or higher (for example, 1300° C.). That is, in the silicon film forming process of Comparative Example 2, the heating temperature of the SiC substrate 12 is higher than that in the silicon film forming process of the present embodiment. When the silicon film forming process is carried out at such a high temperature, silicon atoms move by migration in the silicon film 42 that grows, and an aggregation portion 46 of silicon is formed on a part of the side surface 24a of the trench 24 as shown in FIG. 4A. In the aggregation portion 46, a thickness of the silicon film 42 becomes locally thicker. Therefore, as shown in FIG. 4B, when the trench gate structure is completed, a part of the aggregation portion 46 (that is, the silicon layer) remains unoxidized. If the aggregation portion 46 remains adjacent to the body region as shown in FIG. 4B, a leakage current flows between the source and the drain of the MOS transistor.

In contrast, in the manufacturing method of the present embodiment, the surface of the SiC substrate is etched in the high-temperature hydrogen etching process, and then the silicon film forming process is carried out at a lower heating temperature than the high-temperature hydrogen etching process. In the high-temperature hydrogen etching process, the SiC substrate 12 is heated to a high temperature, so that the surface of the SiC substrate 12 can be appropriately cleaned. In the silicon film forming process, the temperature of the SiC substrate 12 is controlled to a lower temperature than in the high-temperature hydrogen etching process, so that migration of silicon in the silicon film 42 is suppressed. Therefore, the silicon film 42 can be formed to a uniform thickness, and the occurrence of the aggregation portion 46 can be suppressed. Therefore, according to the manufacturing method of the present embodiment, it is possible to suppress the occurrence of defects due to leakage current.

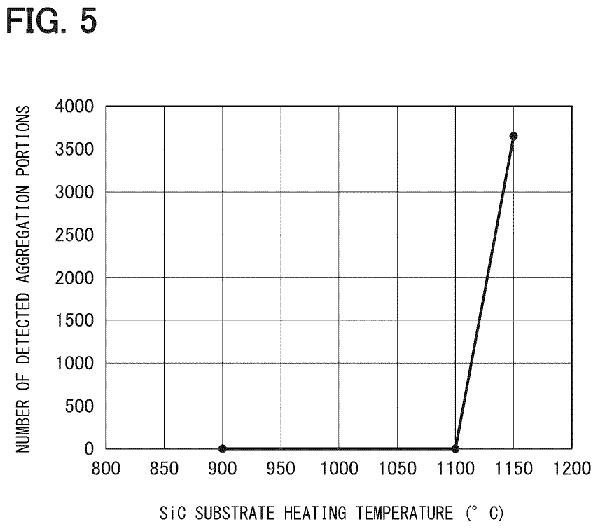

FIG. 5 shows the results of evaluating the number of locations where aggregation portions 46 occur when the silicon film forming process is carried out at different temperatures. When the heating temperature of the SiC substrate in the silicon film forming process was 1150° C., the number of aggregation portions 46 occurred per wafer was 3653, whereas when the heating temperature was 1100° C. or 900° C., the number of aggregation portions 46 occurred per wafer was 0. In this manner, by controlling the heating temperature of the SiC substrate in the silicon film forming process to 1100° C. or less, the occurrence of the aggregation portion 46 can be significantly suppressed.

In the above-described embodiment, the manufacturing method of the MOS transistor having the trench gate structure has been described. However, the techniques disclosed in the present specification may also be applied to a manufacturing method of MOS transistors having a planar gate structure. In this case, the techniques disclosed in the present specification make it possible to form a gate insulating film so as to cover a main surface (for example, the upper surface) of the SiC substrate. However, since aggregation portions of silicon are likely to occur inside trenches, greater effects can be obtained by using the techniques disclosed in the present specification in manufacture of MOS transistors having a trench gate structure.

Although the embodiments have been described in detail above, these are merely examples and do not limit the scope of claims. The techniques described in the claims include various modifications and modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A manufacturing method of a metal oxide semiconductor transistor, comprising:
etching a surface of a silicon carbide (SiC) substrate by heating the SiC substrate in hydrogen gas;
after carrying out the etching, growing a silicon film on the surface of the SiC substrate by heating the SiC substrate in a gas containing hydrogen gas and a silicon source gas to a temperature lower than a heating temperature of the SiC substrate in the etching;
forming a gate insulating film made of silicon oxide on a surface of the silicon film; and
after the forming of the gate insulating film, carrying out a nitrogen termination process on the SiC substrate.

2. The manufacturing method according to claim 1, further comprising
forming a trench on the surface of the SiC substrate, wherein
the etching of the surface of the SiC substrate includes etching a side surface of the trench,
the growing of the silicon film includes growing the silicon film on the side surface of the trench, and
the forming of the gate insulating film includes forming the gate insulating film on the surface of the silicon film covering the side surface of the trench.

3. The manufacturing method according to claim 1, wherein
the growing of the silicon film includes controlling the temperature of the SiC substrate to 1100° C. or less.

4. The manufacturing method according to claim 1, wherein
the growing of the silicon film includes controlling the temperature of the SiC substrate to a temperature equal to or higher than a decomposition temperature of the silicon source gas.

5. The manufacturing method according to claim 1, wherein
the growing of the silicon film is carried out so that the silicon film has a thickness of 6 nm or less.

6. The manufacturing method according to claim 1, wherein
the etching of the surface of the SiC substrate and the growing of the silicon film are carried out in a same chamber.

7. The manufacturing method according to claim 1, further comprising
forming a sacrificial oxide film on the surface of the SiC substrate and then removing the sacrificial oxide film before the etching of the surface of the SiC substrate.

8. The manufacturing method according to claim 1, wherein
the surface of the SiC substrate is a surface of an epitaxial layer.

9. The manufacturing method according to claim 1, wherein
the forming of the gate insulating film is carried out by chemical vapor deposition.

10. The manufacturing method according to claim 1, wherein
the nitrogen termination process includes heating the SiC substrate to a temperature of 1200° C. or higher in nitrogen gas or nitrogen oxide gas.
